(19) United States
(12) Patent Application Publication
(10) Pub. No.: US 2023/0093535 A1
(43) Pub. Date: Mar. 23, 2023

(54) APPARATUS AND METHOD FOR AUTOMATED GRID VALIDATION

(71) Applicant: FEI Company, Hillsboro, OR (US)

(72) Inventors: Pavol KARLÍK, Brno (CZ); Luká{hacek over (s)} HUBNER, Brno (CZ); Dennis VYMER, Brno (CZ); Iris KICO, Brno (CZ)

(73) Assignee: FEI Company, Hillsboro, OR (US)

(21) Appl. No.: 17/948,531

(22) Filed: Sep. 20, 2022

Related U.S. Application Data
(60) Provisional application No. 63/246,186, filed on Sep. 20, 2021.

(51) Int. Cl. H01J 37/302; H01J 37/28

(52) U.S. Cl. CPC H01J 37/3023; H01J 37/28; H01J 2237/20207; H01J 2237/20214; H01J 2237/20292

(57) ABSTRACT

Apparatuses and methods for automated grid validation are disclosed herein. An example method at least includes imaging a grid, the grid including a support portion and a plurality of posts extending from the support portion, wherein each post of the plurality of posts has a designated weld location, and determining, based on the image, whether the designated weld location of each post of the plurality of posts is valid.

This application claims priority from U.S. Provisional Application No. 63/246,186 filed Sep. 20, 2021 which is hereby incorporated by reference.

### BACKGROUND

Industrial use of charged particle microscopes to form samples and perform subsequent imaging and analysis conventionally uses a process to form a lamella and mount the lamella on an imaging fixture. These fixtures may include posts designated for mounting of a lamella. Because the microscopic sizes of both the lamellae and the fixtures, it is critical that the fixtures be evaluated to determine whether they are in fact useable. For example, locations on the posts designated for attachment of a lamella need to be reviewed to ensure they aren't defective or contamination prior to attachment of lamella. If such defective or contaminated posts are inadvertently used, imaging the lamella may not be possible, which results in a wasted opportunity, time, and expense. Although most of the validation process may traditionally be performed by a skilled user, such work is time consuming and subjective on the skill of the user. As such, automated grid evaluation is desired in such industries.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is an example dual beam charged particle microscope in accordance with an embodiment of the present disclosure.

FIGS. 2A and 2B are example halfmoon grids.

FIG. 3 is an example workflow illustrating various grid validation processes in accordance with an embodiment of the present location.

FIG. 4A is an example of initial input and output of a CNN, which segments the image.

FIGS. 4B, 4C and 4D show examples of a flipped grid, bent grid, and tilted grid/post, respectively.

FIG. 5A shows example of the initial input and output of segmentation CNN.

FIGS. 5B, 5C, 5D and 5E show examples of a lamellae already mounted at weld location, contamination and weld locations, a bent post, and comparison of a good post and a bent post, respectively.

FIG. 6 is a block diagram of a scientific instrument support module for performing support operations, in accordance with various embodiments disclosed herein.

FIG. 7 is a flow diagram of a method of performing support operations, in accordance with various embodiments.

FIG. 8 is a block diagram of a computing device that may perform some or all of the scientific instrument support methods disclosed herein, in accordance with various embodiments.

FIG. 9 is a block diagram of an example scientific instrument support system in which some or all of the scientific instrument support methods disclosed herein may be performed, in accordance with various embodiments.

### DETAILED DESCRIPTION

Disclosed herein are scientific instrument support systems, as well as related methods, computing devices, and computer-readable media. For example, in some embodiments, one or more computing algorithms are used to locate a grid and its posts, determine whether weld locations on each post are viable, and store stage locations associated with locating each weld location at a processing location of the scientific support instrument. Determining whether the weld locations are viable include using the one or more algorithms to assess the condition of the grid posts and the weld locations and noting the stage location for each weld location that is assessed as useable. In some examples, the scientific support instrument is a dual beam charged particle microscope (DB CPM) that includes a focused ion beam (FIB) column and a scanning electron microscope (SEM) column, where the grid is mounted on a moveable stage of the DB CPM for and used for mounting lamellae on for subsequent imaging analysis, such as by transmission electron microscopy (TEM) or scanning transmission electron microscopy (STEM).

The scientific instrument support embodiments disclosed herein may achieve improved performance relative to conventional approaches. For example, conventional approaches rely on skilled technicians to perform all of the tasks automated by the disclosed techniques, which is inefficient and prone to user error. The inefficiency arises in terms of operation time and accuracy, whereas the additional error is due to faulty interpretation of the images, for example. The disclosed techniques, which automates an important aspect of lamella lift out workflows, should lead to enhanced workflow accuracy, and may also increase throughput.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the subject matter disclosed herein. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrases “A and/or B” and “A or B” mean (A), (B), or (A and B). For the purposes of the present disclosure, the phrases “A, B, and/or C” and “A, B, or C” mean (A), (B), (C), (A and B), (A and C), (B and C), or (A, B, and C). Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices.

The description uses the phrases “an embodiment,” “various embodiments,” and “some embodiments,” each of which may refer to one or more of the same or different embodiments. Furthermore, the terms “comprising,” “including,” “having,” and the like, as used with respect to embodiments of the present disclosure, are synonymous. When used to describe a range of dimensions, the phrase “between X and Y” represents a range that includes X and Y. As used herein, an “apparatus” may refer to any individual device or collection of devices. The drawings are not necessarily to scale.

The disclosed techniques encompass analysis steps taken to qualify whether a grid loaded into a DB system is useable for attachment of a lamella. Stated another way, the disclosed techniques include the validation of both grid and its grid posts through analysis, and that the overall grid or each of the individual grid posts is viable for lamella attachment. Prior solutions include substantial manual operation and analysis by a skilled technician to determine whether the grid was loaded correctly, whether the grid posts were oriented as desired and free of defects and contamination so that a lamella could be welded to desired locations on the grid posts. If the grid was mis-oriented, either rotated or translated and/or whether it was loaded is a flipped orientation, the technician would need to move the grid to the desired location using stage movements to address the rotation/translation issues, but would need to vent the system and flip the grid if loaded incorrectly. Contaminated areas on the grid posts would need to be noted so they are not used for lamella welding. Although a skilled technician can perform the needed analysis and corrections, such work is time-consuming. A desire for a more automated process for grid validation is desired.

The disclosed techniques utilize various image analysis algorithms, some or all of which can be implemented using Machine Learning or artificial neural networks, to perform the grid validation workflow. The workflow may proceed in various steps but results in identifying a number of useable post locations along with associated stage coordinates for each useable location. For example, a grid having three posts with each post having three possible weld locations is analyzed to determine which possible weld locations are useable, e.g., defect and contamination free, and the stage locations to move each weld location into the DB operating location is stored. Post analysis, the DB can pick out lamella from a sample in the DB chamber and automatically weld them to a useable post location without user guidance. The system may then progress through each useable weld location for placing a lamella.

The overall workflow may position the grid, which is mounted on a moveable stage, under the SEM and/or the FIB columns so that images of the grid may be acquired. An initial analysis may be performed to determine whether the grid is correctly loaded in the grid mount. An incorrectly loaded is where the grid is in a flipped orientation—grids are not symmetric from front to back and a front side is intended to be facing the SEM and FIB columns. It should be noted that a front-back symmetric grid may not need such a step. If the grid was loaded wrong, then the system may need to be vented so that a user can physically re-orient the grid. Alternatively, a mechanical flipping mechanism may be engaged to re-orient the grid.

With the grid correctly mounted, the workflow may proceed to translate the grid into a desired location so that all grid posts are identified. In some embodiments, the number of posts is known by the algorithm a priori so that by analyzing the image, a quick determination may be made of whether all grids are observable. If not, then the system may move the stage around, acquire another image and perform the analysis. These steps may be repeated until the grid is at least grossly in the correct location. Alternatively, if the algorithm is implemented in a ML/AI model that has been trained on different grid types, e.g., different numbers of posts that have different post sizes and spacings, then the system can determine both the type of grid and whether the grid is positioned correctly. If not positioned correctly, the same move, image, analyze steps may be repeated until it is in the desired position.

Once the “gross” positioning of the grid is executed, finer positioning for grid orientation, e.g., rotation and/or tilt, may be performed. In some examples, both coarse and fine orientation may be performed concurrently. The positioning may also result in determination of the location of each post and the associated stage position vectors of each post location. In general, the post positions are the desired information since the posts are where the lamella will be welded.

Once the posts are located, each post will be further analyzed for defects, contamination and the weld locations assessed. The defect analysis determines whether the post suffered any physical damage, which may be due to either handling or fabrication issues. For example, a post may be bent in any direction or contain defects, such as burrs or missing material. In addition to defects, an algorithm is used to assess whether the post is contaminated with debris, due to handling for example, and whether that debris, if present, encroaches on a weld location. It should be noted that the weld locations are also identified, which are conventionally on the top, left and right sides of a post, which helps determine whether the weld location is useable. If the post is defective, then the entire post may be deemed unusable. However, if only debris is present, then one, two or three of the weld locations may be identified as useable based on the size and proximity of the debris with respect to each weld location. In one example, an area larger than the actual lamella may be identified as the weld location and any debris within the identified weld location may disqualify the weld location as useable.

In addition to determining whether each post contains useable weld location, an algorithm may also determine whether a lamella has already been welded to a post in the weld location. This may happen if a used grid is somehow reused due to lab error, for example. A post with a lamella already present would be deemed unusable.

After all posts and associated weld locations are characterized, then the system stores the physical stage locations of each useable weld location so that during lamella lift out and weld, the system can automatically navigate to each weld location for a lamella to be welded thereon.

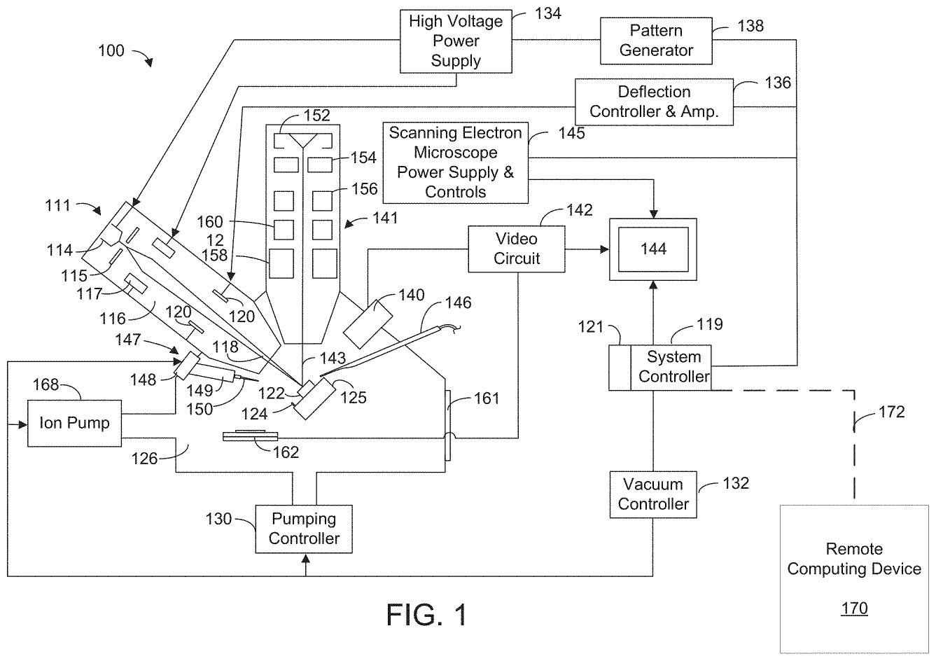

FIG. 1. is an example dual beam system 100 in accordance with a disclosed embodiment. While an example of suitable hardware is provided below, the invention is not limited to being implemented in any particular type of hardware. Instead, the techniques disclosed herein may be implemented on any instrument that mounts lamella, or similarly sized samples, onto structures used for subsequent analysis. The examples used herein may be lamellae taken from semiconductor samples and mount to posts of, what are conventionally referred to as, half-moon grids. The grids may be transferred to a TEM for imaging or may be imaged in a STEM. In some examples, the STEM imaging may be performed by the DB system that formed the lamella and executed the grid validation workflow disclosed herein.

A scanning electron microscope (SEM) 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflection coil 160. Operation of condensing lens 156, objective lens 158, and deflection coil 160 is controlled by power supply and control unit 145.

Electron beam 143 can be focused onto substrate 122, which is on movable X-Y stage 125 within lower chamber 126. When the electrons in the electron beam strike substrate 122, secondary electrons are emitted. These secondary electrons are detected by secondary electron detector 140 as discussed below. STEM detector 162, located beneath the TEM sample holder 124 and the stage 125, can collect electrons that are transmitted through the sample mounted on the TEM sample holder as discussed above.

Dual beam system 110 also includes focused ion beam (FIB) system in which comprises an evacuated chamber having an upper neck portion 112 within which are located an ion source 114 and a focusing column 116 including extractor electrodes and an electrostatic optical system. The axis of focusing column 116 is tilted 52 degrees from the axis of the electron column. The ion column 112 includes an ion source 114, an extraction electrode 115, a focusing element 117, deflection elements 120, and a focused ion beam 118. Focused ion beam 118 passes from ion source 114 through focusing column 116 and between electrostatic deflection means schematically indicated at 120 toward substrate 122, which comprises, for example, a semiconductor device positioned on movable X-Y stage 125 within lower chamber 126.

Stage 125 can preferably move in a horizontal plane (X and Y axes) and vertically (Z axis). Stage 125 can also tilt approximately sixty (60) degrees and rotate about the Z axis. In some embodiments, a separate TEM sample stage (not shown) can be used. Such a TEM sample stage will also preferably be moveable in the X, Y, and Z axes. TEM sample holder 124 may be used for holding TEM halfmoon grids (referred to herein simply as a “grid” or “grids”), which are used for mounting lamellae to for subsequent S/TEM imaging. A door 161 is opened for inserting substrate 122 onto X-Y stage 125 and also for loading one or more grids onto TEM sample holder 124. The door is interlocked so that it cannot be opened if the system is under vacuum.

An ion pump 168 is employed for evacuating neck portion 112. The chamber 126 is evacuated with turbomolecular and mechanical pumping system 130 under the control of vacuum controller 132. The vacuum system provides within chamber 126 a vacuum of between approximately 1×10-7 Torr and 5×10-4 Torr. If an etch assisting, an etch retarding gas, or a deposition precursor gas is used, the chamber background pressure may rise, typically to about 1×10-5 Torr.

The high voltage power supply provides an appropriate acceleration voltage to electrodes in focusing column 116 for energizing and focusing ion beam 118. When it strikes substrate 122, material is sputtered, that is physically ejected, from the sample. Alternatively, ion beam 118 can decompose a precursor gas to deposit a material.

High voltage power supply 134 is connected to liquid metal ion source 114 as well as to appropriate electrodes in ion beam focusing column 116 for forming an approximately 1 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of substrate 122 when a blanking controller (not shown) applies a blanking voltage to the blanking electrode.

The liquid metal ion source 114 typically provides a metal ion beam of gallium. The source typically is capable of being focused into a sub one-tenth micrometer wide beam at substrate 122 for either modifying the substrate 122 by ion milling, enhanced etch, material deposition, or for the purpose of imaging the substrate 122.

A charged particle detector 140, such as an Everhart Thornley or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into lower chamber 126 for introducing and directing a gaseous vapor toward substrate 122. U.S. Pat. No. 5,851,413 to Casella et al. for “Gas Delivery Systems for Particle Beam Processing,” assigned to the assignee of the present invention, describes a suitable gas delivery system 146. Another gas delivery system is described in U.S. Pat. No. 5,435,850 to Rasmussen for a “Gas Injection System,” also assigned to the assignee of the present invention. For example, iodine can be delivered to enhance etching, or a metal organic compound can be delivered to deposit a metal.

System controller 119 controls the operations of the various parts of dual beam system 110. Through system controller 119, a user can cause ion beam 118 or electron beam 143 to be scanned in a desired manner through commands entered into a conventional user interface (not shown). Alternatively, system controller 119 may control dual beam system 100 in accordance with programmed instructions stored in a memory 121. In some embodiments, dual beam system 100 incorporates image recognition software to automatically identify regions of interest, and then the system can manually or automatically determine the state of useability of such regions of interest in accordance with the invention. For example, the system could automatically locate a grid mounted on the TEM sample holder 124 and determine the quality of the grid, whether each post is useable, and further whether each identified weld location on each post is useable. For each useable weld location, an associated stage coordinate, in X, Y, Z, alpha, and theta, for example, is stored for automatic retrieval and navigation. As used herein, alpha and theta refer to stage tile and stage rotation.

In some examples, DB system 100 may be coupled to remote computing device 170 via network 172. Remote computing device 170 may hold code and models for implementing the deep learning techniques disclosed herein and/or the code and models may be stored in memory 121. Either way, the code and models may include pre-trained or untrained artificial neural networks (ANNs) to assist in validating grids and grid posts for accepting lamella. In some examples, the ANNs may be implemented as multiple convolutional neural networks (CNNs) for performing specific image recognition tasks that are used for validating grids. For example, a first CNN (CNN1) may include a segmentation model used for grid post detection and some of the quality validations disclosed herein. A second CNN (CNN2) may include a classifier model used for grid placement detection, which outputs a percentage specifying the model's confidence of whether a grid is properly placed. A third CNN (CNN3) includes a segmentation model that outputs lamellae segments found in the image, and which is used to determine if a lamella is already in a weld position. A fourth CNN (CNN4) includes a segmentation model that outputs contamination segments found in an image.

In operation, the controller causes the stage to move so that the TEM holder 124 with a grid mounted thereon is in a position for imaging with the SEM 141, for example. One or more images may be acquired of the grid at various fields of view (FOV), but these images may be at a wide FOV and at an associated low magnification so that the entire grid is captured in the image. Or, a low mag, wide FOV image may be acquired of where the grid should be located based on the stage movement. The image is then analyzed using the various CNNs to determine whether the posts of the grids are useable, e.g., valid, and further whether each weld location is useable. For each useable location, associated stage vectors are stored for later retrieval, whereas non-useable locations are ignored.

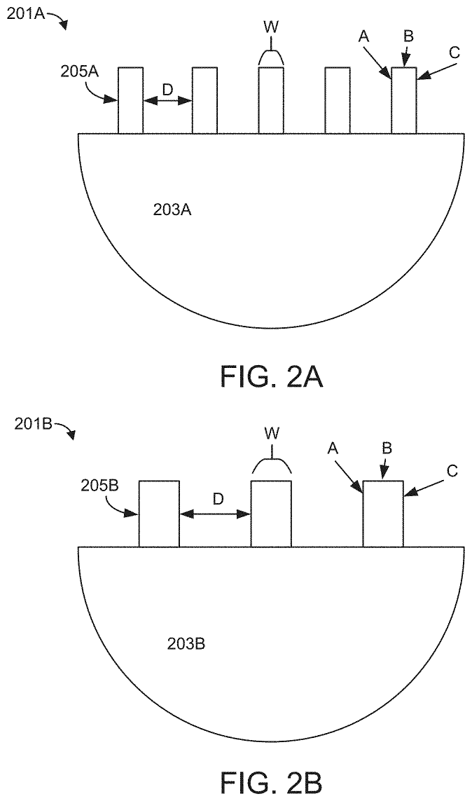

FIGS. 2A and 2B are example halfmoon grids. FIG. 2A shows a halfmoon grid 201A that includes a body 203A and a plurality of posts 205A. Each post 205A has a width W and are separated by a distance D. Each post 205A may have three locations that can potentially be used for welding a lamella on to. For example, locations A, B and C may be used at potential weld locations. FIG. 2B shows a halfmoon grid 201B having the same features as grid 201A but with fewer posts 205B that are larger and differently spaced than posts 205A. However, posts 205B may have the same potential weld locations as posts 205A.

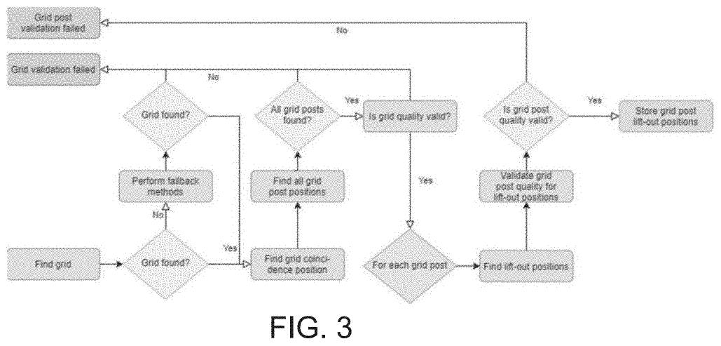

FIG. 3 is an example workflow 301 illustrating various grid validation processes in accordance with an embodiment of the present location. The workflow 301 may be implemented on an instrument that transfers lamella to a grid and the workflow may be implemented so that only grid posts with useable weld locations are used for attachment of a lamella. In general, workflow 301 makes a series of determinations before storing a stage location of a useable weld location. Some of the determinations may logically follow a sequence, but some of the determination can be performed at any time.

Workflow 301 may be described as having two major functional aspects—a grid validation aspect and a grid post validation aspect. The grid validation aspect analyses one or more images of the grid to determine if the grid was loaded correctly, where the grid is located with respect to where is was expected to be, and whether the grid is tilted. An incorrectly loaded grid is one that is loaded in a flipped orientation. Whether the grid is located where expected may be based on whether the number of posts shown in the image matches the number of posts expected, and further how the location of each post relate to the image. The grid can also be tilted and/or rotated when loaded into the system, which can be determined from the image.

With regards to the grid post validation aspect of workflow 301, the image or images of the grids are analyzed to locate the potential weld locations and further analyzed to determine whether the weld locations are useable. The preset grid locations are located, and the identified area may be larger than an actual lamella to ensure the analysis account for variability in placement and reduce encroachment of any contamination. Additionally, the grids are analyzed for contamination, whether any of the posts are defective, and whether a lamella is already located in the weld locations. Contamination that encroaches on a weld location may result in that weld location being deemed unusable, but general contamination that does not affect a weld location, may be ignored. The determination of whether a lamella is already in a weld location is performed to ensure used grids are inadvertently used, which would make such a weld location, if not the grid, unusable. Further analysis of the posts' condition may also be performed as well. Lastly, defected posts are monitored for based on the overall shape of the post to determine if the post is bent, for example. Upon identification of valid weld locations, the workflow may end with storing the stage locations associated with positioning each valid, e.g., useable, weld location at the location for processing by a charged particle beam, for example.

As noted, the grid validation and grid post validation processes may be implemented using computing code executed by one or more processors. Such code may implement conventional image processing techniques including the appropriate decision-making logic based on the image analysis. Alternatively, the processes may be implemented using one or more CNNs having trained models to make the desired determinations.

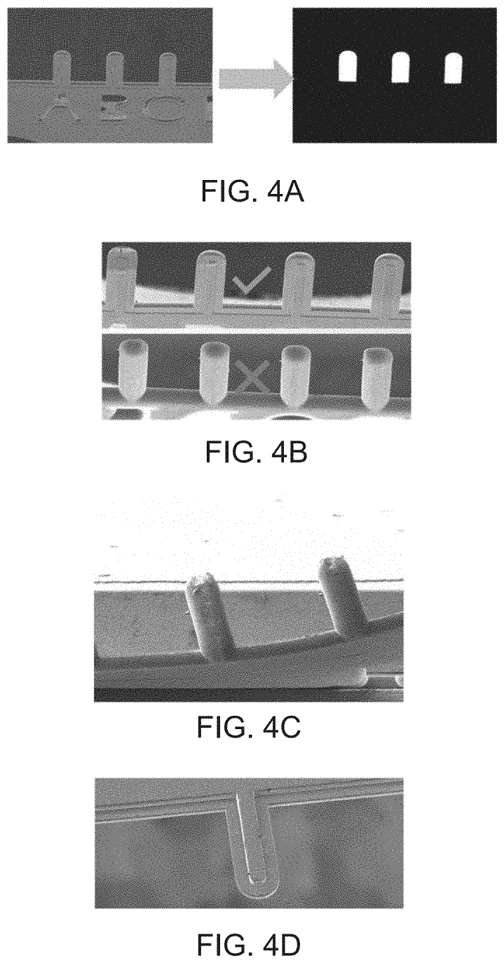

For the grid validation steps of workflow 301, CNNs may be used to make the desired determinations regarding the grid. For example, using the CNNs discussed above with respect to FIG. 1, CNN2 may be used for evaluating whether the grid is correctly placed onto the grid holder. (Note that the grid placement is analyzed in both grid and grid post validation phases, which ensures that the improperly placed grid is detected with significantly higher accuracy.) CNN1 may be used for bent grid detection, which uses detected grid post upper tips as points, linear regression is then utilized to calculate parabola and line coefficients, based on which the evaluation is performed to determine whether the grid is bent. Additionally, CNN1 may also be used to determine if the grid is tilted using grid post bottom position as points, linear regression is utilized to calculate grid tilt. In some examples, the grid tilt of ±3 degrees is the threshold of determining grid tilt. Of course, other thresholds are contemplated and useable. In general, grid validation consists of verifying whether the grid is tilted, bent, or oppositely placed. FIG. 4A is an example of initial input and output of CNN1, which segments the image. The segmented image, e.g., the output of CNN1, shown in FIG. 4A may also be used as the input to CNN2, which determines grid placement. Once a grid is considered as invalid, the grid is rejected. FIGS. 4B, 4C and 4D show examples of a flipped grid, bent grid, and tilted grid/post, respectively. The analysis by the CNNs may be performed on the image themselves or on a segmented image, as shown in FIG. 4A.

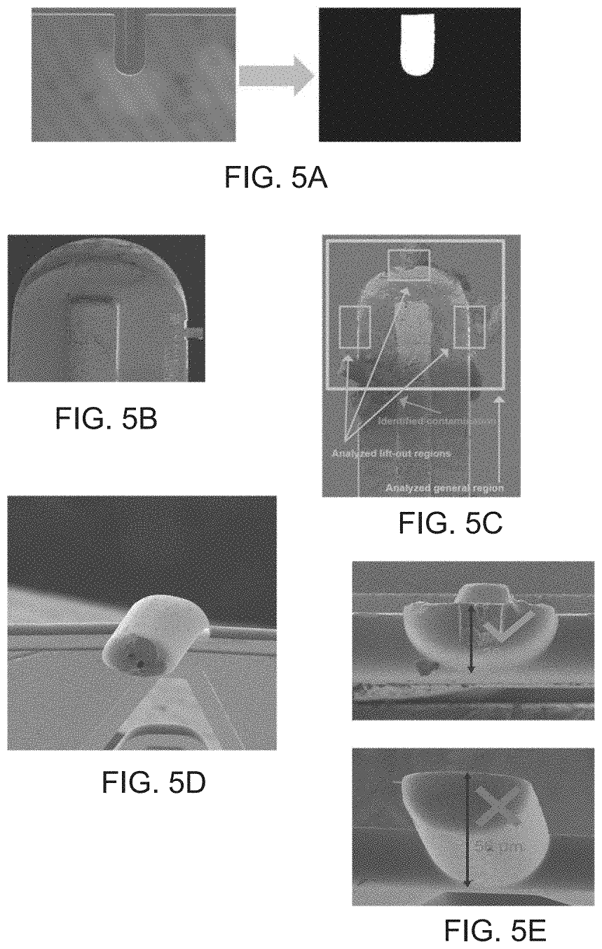

For the grid posts validation steps of workflow 301, CNNs may again be used to make the associated determination regarding the posts and the weld locations. For example, using the CNNs discussed above with respect to FIG. 1, CNN3 may be sued to detect the presence of a lamella on a post at a weld location. CNN4 may be used for detecting contamination on a grid. The CNN4 model performs image segmentation and determines whether there is contamination on the identified weld locations in addition to whether there is general contamination at the end of the grid posts. Additionally, CNN1 may be used to detect for bent or tilted grid posts. For bent grid detection, a grid post segment shape is used to verify whether the post is bent, utilizing linear regression for example, and center points of the segmented grid post are used as points to calculate line and parabola coefficients, for example. For tilted grid detection, segmented shape is used to estimate tilt, utilizing linear regression for example, and center points of the segmented grid post are used as points to calculate line coefficients. In general, grid post validation consists of verifying whether each weld location of a grid post is useable for welding a lamella thereto. FIG. 5A shows example of the initial input and output of segmentation CNN, such as CNN1. FIGS. 5B, 5C, 5D and 5E show examples of a lamellae already mounted at weld location, contamination and weld locations, a bent post, and comparison of a good post and a bent post, respectively.

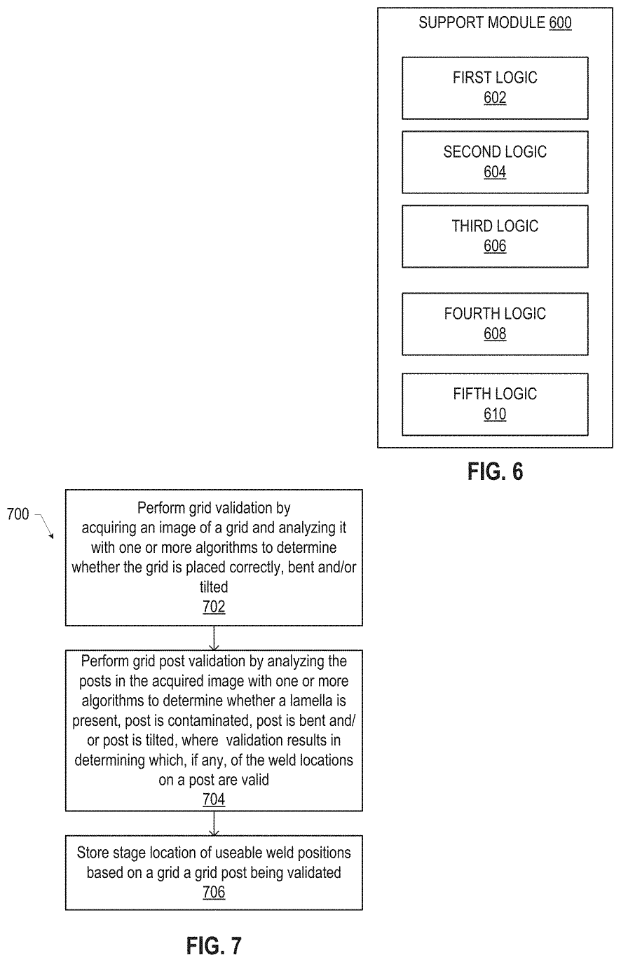

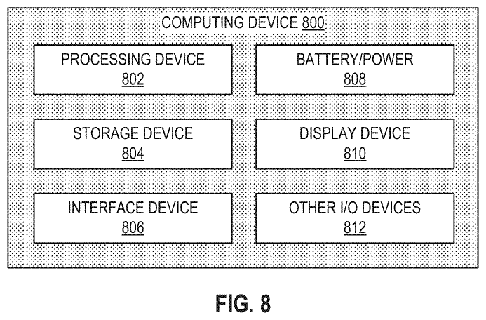

FIG. 6 is a block diagram of a scientific instrument support module 600 for performing support operations, in accordance with various embodiments disclosed herein. The scientific instrument support module 600 may be implemented by circuitry (e.g., including electrical and/or optical components), such as a programmed computing device. The logic of the scientific instrument support module 600 may be included in a single computing device or may be distributed across multiple computing devices that are in communication with each other as appropriate. Examples of computing devices that may, singly or in combination, implement the scientific instrument support module 600 are discussed herein with reference to the computing device 700 of FIG. 7, and examples of systems of interconnected computing devices, in which the scientific instrument support module 600 may be implemented across one or more of the computing devices, is discussed herein with reference to the scientific instrument support system 800 of FIG. 8. Additionally, module 600 may be implemented in DB CPM 100, such as in controller 119, memory 121, remote computing device 170, and combinations thereof.

The scientific instrument support module 600 may include first logic 602, second logic 604, third logic 606, fourth logic 608, and fifth logic 610. As used herein, the term “logic” may include an apparatus that is to perform a set of operations associated with the logic. For example, any of the logic elements included in the support module 600 may be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” may refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices.

The first logic 602 may include the model and network to implement CNN1, as discussed above. In general, first logic 602 may segment images used for the various grid and post determinations disclosed above. Additionally, the output of the first logic may be used as an input to second, third and fourth logics.

The second logic 604 may include the model and network to implement CNN1, as discussed above. In general, CNN2 may be a classifier model used to detect various components of a grid and grid posts, and further determine whether a grid is placed, e.g., loaded, properly.

The third logic 606 may include the model and network to implement CNN3, as discussed above. In general, third logic 606 may segment an image and make a determination of whether a lamella is already in a weld location.

The fourth logic 608 may include the model and network to implement CNN4, as discussed above. The fourth logic 608 may also be a segmentation CNN that identifies contamination in an image.

The fifth logic 610 may include analytical processing logic used to make various determinations using the outputs of CNNs 1 through 4. For example, a segmented image output by CNN1 may be analyzed by the fifth logic 610 to make calculations to determine whether the grid or grid posts are bent or tilted, such as by performing various linear regressions.

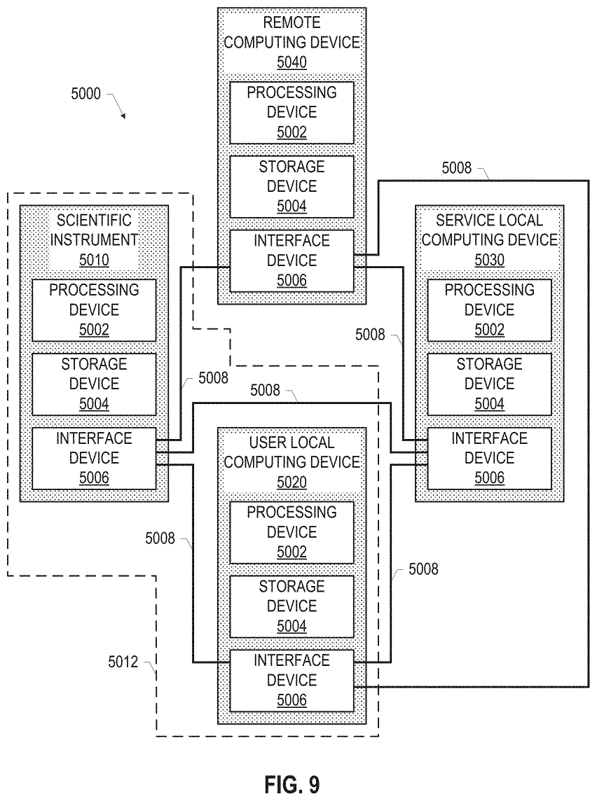

FIG. 7 is a flow diagram of a method 700 of performing support operations, in accordance with various embodiments. Although the operations of the method 700 may be illustrated with reference to particular embodiments disclosed herein (e.g., the scientific instrument support modules 600 discussed herein with reference to FIG. 6, the computing devices 800 discussed herein with reference to FIG. 8, and/or the scientific instrument support system 900 discussed herein with reference to FIG. 9), the method 700 may be used in any suitable setting to perform any suitable support operations. Operations are illustrated once each and in a particular order in FIG. 7, but the operations may be reordered and/or repeated as desired and appropriate (e.g., different operations performed may be performed in parallel, as suitable).

At 702, first operations may be performed. For example, the first and second logics 602 and 604 of a support module 600 may perform the operations of 702. The first operations may include performing grid validation. Grid validation may at least include acquiring an image of a grid and analyzing it with one or more algorithms to determine whether the grid is placed correctly, bent and/or tilted.

At 704, second operations may be performed. For example, the first, third and fourth logics 602, 606 and 608 of a support module 600 may perform the operations of 704. The second operations may include performing grid post validation. Grid post validation may at least include analyzing the posts in the acquired image with one or more algorithms to determine whether a lamella is present, a post is contaminated, a post is bent and/or a post is tilted. Such validation results in determining which, if any, of the weld locations on a post are valid, e.g., useable.

At 706, third operations may be performed. For example, the fifth logic 610 of a support module 600 may perform the operations of 706. The third operations may include storing stage location information associated with each validated post weld location.

The scientific instrument support methods disclosed herein may include interactions with a human user (e.g., via the user local computing device 5020 discussed herein with reference to FIG. 9). These interactions may include providing information to the user (e.g., information regarding the operation of a scientific instrument such as the scientific instrument 5010 of FIG. 9, information regarding a sample being analyzed or other test or measurement performed by a scientific instrument, information retrieved from a local or remote database, or other information) or providing an option for a user to input commands (e.g., to control the operation of a scientific instrument such as the scientific instrument 5010 of FIG. 9, or to control the analysis of data generated by a scientific instrument), queries (e.g., to a local or remote database), or other information. In some embodiments, these interactions may be performed through a graphical user interface (GUI) that includes a visual display on a display device (e.g., the display device 810 discussed herein with reference to FIG. 8) that provides outputs to the user and/or prompts the user to provide inputs (e.g., via one or more input devices, such as a keyboard, mouse, trackpad, or touchscreen, included in the other I/O devices 812 discussed herein with reference to FIG. 8). The scientific instrument support systems disclosed herein may include any suitable GUIs for interaction with a user.

As noted above, the scientific instrument support module 600 may be implemented by one or more computing devices. FIG. 8 is a block diagram of a computing device 4000 that may perform some or all of the scientific instrument support methods disclosed herein, in accordance with various embodiments. In some embodiments, the scientific instrument support module 1000 may be implemented by a single computing device 4000 or by multiple computing devices 4000. Further, as discussed below, a computing device 800 (or multiple computing devices 800) that implements the scientific instrument support module 1000 may be part of one or more of the scientific instrument 5010, the user local computing device 5020, the service local computing device 5030, or the remote computing device 5040 of FIG. 9.

The computing device 800 of FIG. 8 is illustrated as having a number of components, but any one or more of these components may be omitted or duplicated, as suitable for the application and setting. In some embodiments, some or all of the components included in the computing device 800 may be attached to one or more motherboards and enclosed in a housing (e.g., including plastic, metal, and/or other materials). In some embodiments, some these components may be fabricated onto a single system-on-a-chip (SoC) (e.g., an SoC may include one or more processing devices 802 and one or more storage devices 804). Additionally, in various embodiments, the computing device 800 may not include one or more of the components illustrated in FIG. D, but may include interface circuitry (not shown) for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 800 may not include a display device 810, but may include display device interface circuitry (e.g., a connector and driver circuitry) to which a display device 810 may be coupled.

The computing device 800 may include a processing device 802 (e.g., one or more processing devices). As used herein, the term “processing device” may refer to any device or portion of a device that processes electronic data from registers and/or memory to transform that electronic data into other electronic data that may be stored in registers and/or memory. The processing device 802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 800 may include a storage device 804 (e.g., one or more storage devices). The storage device 804 may include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 804 may include memory that shares a die with a processing device 802. In such an embodiment, the memory may be used as cache memory and may include embedded dynamic random access memory (eDRAM) or spin transfer torque magnetic random access memory (STT-MRAM), for example. In some embodiments, the storage device 804 may include non-transitory computer readable media having instructions thereon that, when executed by one or more processing devices (e.g., the processing device 802), cause the computing device 800 to perform any appropriate ones of or portions of the methods disclosed herein.

The computing device 800 may include an interface device 806 (e.g., one or more interface devices 806). The interface device 806 may include one or more communication chips, connectors, and/or other hardware and software to govern communications between the computing device 800 and other computing devices. For example, the interface device 806 may include circuitry for managing wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. Circuitry included in the interface device 806 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). In some embodiments, circuitry included in the interface device 806 for managing wireless communications may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 806 for managing wireless communications may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 806 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 806 may include one or more antennas (e.g., one or more antenna arrays) to receipt and/or transmission of wireless communications.

In some embodiments, the interface device 806 may include circuitry for managing wired communications, such as electrical, optical, or any other suitable communication protocols. For example, the interface device 806 may include circuitry to support communications in accordance with Ethernet technologies. In some embodiments, the interface device 806 may support both wireless and wired communication, and/or may support multiple wired communication protocols and/or multiple wireless communication protocols. For example, a first set of circuitry of the interface device 806 may be dedicated to shorter-range wireless communications such as Wi-Fi or Bluetooth, and a second set of circuitry of the interface device 806 may be dedicated to longer-range wireless communications such as global positioning system (GPS), EDGE, GPRS, CDMA, WiMAX, LTE, EV-DO, or others. In some embodiments, a first set of circuitry of the interface device 806 may be dedicated to wireless communications, and a second set of circuitry of the interface device 806 may be dedicated to wired communications.

The computing device 800 may include battery/power circuitry 808. The battery/power circuitry 808 may include one or more energy storage devices (e.g., batteries or capacitors) and/or circuitry for coupling components of the computing device 800 to an energy source separate from the computing device 800 (e.g., AC line power).

The computing device 800 may include a display device 810 (e.g., multiple display devices). The display device 810 may include any visual indicators, such as a heads-up display, a computer monitor, a projector, a touchscreen display, a liquid crystal display (LCD), a light-emitting diode display, or a flat panel display.

The computing device 800 may include other input/output (I/O) devices 812. The other I/O devices 812 may include one or more audio output devices (e.g., speakers, headsets, earbuds, alarms, etc.), one or more audio input devices (e.g., microphones or microphone arrays), location devices (e.g., GPS devices in communication with a satellite-based system to receive a location of the computing device 800, as known in the art), audio codecs, video codecs, printers, sensors (e.g., thermocouples or other temperature sensors, humidity sensors, pressure sensors, vibration sensors, accelerometers, gyroscopes, etc.), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 800 may have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer, etc.), a desktop computing device, or a server computing device or other networked computing component.

One or more computing devices implementing any of the scientific instrument support modules or methods disclosed herein may be part of a scientific instrument support system. FIG. 9 is a block diagram of an example scientific instrument support system 5000 in which some or all of the scientific instrument support methods disclosed herein may be performed, in accordance with various embodiments. The scientific instrument support modules and methods disclosed herein (e.g., the scientific instrument support module 600 of FIG. 6 and the method 700 of FIG. 7) may be implemented by one or more of the scientific instrument 5010, the user local computing device 5020, the service local computing device 5030, or the remote computing device 5040 of the scientific instrument support system 5000.

Any of the scientific instrument 5010, the user local computing device 5020, the service local computing device 5030, or the remote computing device 5040 may include any of the embodiments of the computing device 800 discussed herein with reference to FIG. 8, and any of the scientific instrument 5010, the user local computing device 5020, the service local computing device 5030, or the remote computing device 5040 may take the form of any appropriate ones of the embodiments of the computing device 800 discussed herein with reference to FIG. 8.

The scientific instrument 5010, the user local computing device 5020, the service local computing device 5030, or the remote computing device 5040 may each include a processing device 5002, a storage device 5004, and an interface device 5006. The processing device 5002 may take any suitable form, including the form of any of the processing devices 802 discussed herein with reference to FIG. 8, and the processing devices 5002 included in different ones of the scientific instrument 5010, the user local computing device 5020, the service local computing device 5030, or the remote computing device 5040 may take the same form or different forms. The storage device 5004 may take any suitable form, including the form of any of the storage devices 5004 discussed herein with reference to FIG. 8, and the storage devices 5004 included in different ones of the scientific instrument 5010, the user local computing device 5020, the service local computing device 5030, or the remote computing device 5040 may take the same form or different forms. The interface device 5006 may take any suitable form, including the form of any of the interface devices 806 discussed herein with reference to FIG. 8, and the interface devices 5006 included in different ones of the scientific instrument 5010, the user local computing device 5020, the service local computing device 5030, or the remote computing device 5040 may take the same form or different forms.

The scientific instrument 5010, the user local computing device 5020, the service local computing device 5030, and the remote computing device 5040 may be in communication with other elements of the scientific instrument support system 5000 via communication pathways 5008. The communication pathways 5008 may communicatively couple the interface devices 5006 of different ones of the elements of the scientific instrument support system 5000, as shown, and may be wired or wireless communication pathways (e.g., in accordance with any of the communication techniques discussed herein with reference to the interface devices 806 of the computing device 800 of FIG. 8). The particular scientific instrument support system 5000 depicted in FIG. 9 includes communication pathways between each pair of the scientific instrument 5010, the user local computing device 5020, the service local computing device 5030, and the remote computing device 5040, but this “fully connected” implementation is simply illustrative, and in various embodiments, various ones of the communication pathways 5008 may be absent. For example, in some embodiments, a service local computing device 5030 may not have a direct communication pathway 5008 between its interface device 5006 and the interface device 5006 of the scientific instrument 5010, but may instead communicate with the scientific instrument 5010 via the communication pathway 5008 between the service local computing device 5030 and the user local computing device 5020 and the communication pathway 5008 between the user local computing device 5020 and the scientific instrument 5010.

The scientific instrument 5010 may include any appropriate scientific instrument, such as an SEM, TEM, STEM, FIB, Dual Beam and combinations thereof.

The user local computing device 5020 may be a computing device (e.g., in accordance with any of the embodiments of the computing device 800 discussed herein) that is local to a user of the scientific instrument 5010. In some embodiments, the user local computing device 5020 may also be local to the scientific instrument 5010, but this need not be the case; for example, a user local computing device 5020 that is in a user's home or office may be remote from, but in communication with, the scientific instrument 5010 so that the user may use the user local computing device 5020 to control and/or access data from the scientific instrument 5010. In some embodiments, the user local computing device 5020 may be a laptop, smartphone, or tablet device. In some embodiments the user local computing device 5020 may be a portable computing device.

The service local computing device 5030 may be a computing device (e.g., in accordance with any of the embodiments of the computing device 800 discussed herein) that is local to an entity that services the scientific instrument 5010. For example, the service local computing device 5030 may be local to a manufacturer of the scientific instrument 5010 or to a third-party service company. In some embodiments, the service local computing device 5030 may communicate with the scientific instrument 5010, the user local computing device 5020, and/or the remote computing device 5040 (e.g., via a direct communication pathway 5008 or via multiple “indirect” communication pathways 5008, as discussed above) to receive data regarding the operation of the scientific instrument 5010, the user local computing device 5020, and/or the remote computing device 5040 (e.g., the results of self-tests of the scientific instrument 5010, calibration coefficients used by the scientific instrument 5010, the measurements of sensors associated with the scientific instrument 5010, etc.). In some embodiments, the service local computing device 5030 may communicate with the scientific instrument 5010, the user local computing device 5020, and/or the remote computing device 5040 (e.g., via a direct communication pathway 5008 or via multiple “indirect” communication pathways 5008, as discussed above) to transmit data to the scientific instrument 5010, the user local computing device 5020, and/or the remote computing device 5040 (e.g., to update programmed instructions, such as firmware, in the scientific instrument 5010, to initiate the performance of test or calibration sequences in the scientific instrument 5010, to update programmed instructions, such as software, in the user local computing device 5020 or the remote computing device 5040, etc.). A user of the scientific instrument 5010 may utilize the scientific instrument 5010 or the user local computing device 5020 to communicate with the service local computing device 5030 to report a problem with the scientific instrument 5010 or the user local computing device 5020, to request a visit from a technician to improve the operation of the scientific instrument 5010, to order consumables or replacement parts associated with the scientific instrument 5010, or for other purposes.

The remote computing device 5040 may be a computing device (e.g., in accordance with any of the embodiments of the computing device 800 discussed herein) that is remote from the scientific instrument 5010 and/or from the user local computing device 5020. In some embodiments, the remote computing device 5040 may be included in a datacenter or other large-scale server environment. In some embodiments, the remote computing device 5040 may include network-attached storage (e.g., as part of the storage device 5004). The remote computing device 5040 may store data generated by the scientific instrument 5010, perform analyses of the data generated by the scientific instrument 5010 (e.g., in accordance with programmed instructions), facilitate communication between the user local computing device 5020 and the scientific instrument 5010, and/or facilitate communication between the service local computing device 5030 and the scientific instrument 5010.

In some embodiments, one or more of the elements of the scientific instrument support system 5000 illustrated in FIG. 9 may not be present. Further, in some embodiments, multiple ones of various ones of the elements of the scientific instrument support system 5000 of FIG. 9 may be present. For example, a scientific instrument support system 5000 may include multiple user local computing devices 5020 (e.g., different user local computing devices 5020 associated with different users or in different locations). In another example, a scientific instrument support system 5000 may include multiple scientific instruments 5010, all in communication with service local computing device 5030 and/or a remote computing device 5040; in such an embodiment, the service local computing device 5030 may monitor these multiple scientific instruments 5010, and the service local computing device 5030 may cause updates or other information may be “broadcast” to multiple scientific instruments 5010 at the same time. Different ones of the scientific instruments 5010 in a scientific instrument support system 5000 may be located close to one another (e.g., in the same room) or farther from one another (e.g., on different floors of a building, in different buildings, in different cities, etc.). In some embodiments, a scientific instrument 5010 may be connected to an Internet-of-Things (IoT) stack that allows for command and control of the scientific instrument 5010 through a web-based application, a virtual or augmented reality application, a mobile application, and/or a desktop application. Any of these applications may be accessed by a user operating the user local computing device 5020 in communication with the scientific instrument 5010 by the intervening remote computing device 5040. In some embodiments, a scientific instrument 5010 may be sold by the manufacturer along with one or more associated user local computing devices 5020 as part of a local scientific instrument computing unit 5012.

Example methods and apparatuses for automated grid validation may at least include the following techniques. An example method may include imaging a grid, the grid including a support portion and a plurality of posts extending from the support portion, wherein each post of the plurality of posts has a designated weld location, and determining, based on the image, whether the designated weld location of each post of the plurality of posts is valid.

The example method of above where determining, based on the image, whether the designated weld location of each post of the plurality of posts is valid includes determining, based on the image, whether there is contamination present on or around the weld location.

The example method of above where the determining is performed using an artificial neural network trained to identify contamination.

The example method of above where the artificial neural network is a convolutional neural network.

The example method of above where determining, based on the image, whether the designated weld location of each post of the plurality of posts is valid includes determining, based on the image, whether each post is defective.

The example method of above where the determining is performed using an artificial neural network trained to identify contamination.

The example method of above where the artificial neural network is a convolutional neural network.

The example method of above where defective includes bent, tilted or rotated.

The example method of above where defective includes missing material.

The example method of above where determining, based on the image, whether the designated weld location of each post of the plurality of posts is valid includes determining, based on the image, whether a lamella is already present at the weld location of each post.

The example method of above where the determining is performed using an artificial neural network trained to identify contamination.

The example method of above where the artificial neural network is a convolutional neural network.

The example method of above further including determining, based on the image, whether the grid is valid.

The example method of above where determining, based on the image, whether the grid is valid includes determining, based on the image, whether the grid is located in a designated location.

The example method of above where the determining is performed using an artificial neural network trained to identify contamination.

The example method of above where the artificial neural network is a convolutional neural network.

The example method of above where determining, based on the image, whether the grid is located in a designated location includes determining whether the grid is tilted.

The example method of above where determining, based on the image, whether the grid is located in a designated location includes determining whether the grid is rotated.

The example method of above where determining, based on the image, whether the grid is located in a designated location includes determining whether the grid is flipped.

The example method of above further includes storing a stage location associated with each valid weld location.

1. A method comprising:
imaging a grid, the grid including a support portion and a plurality of posts extending from the support portion, wherein each post of the plurality of posts has a designated weld location; and
determining, based on the image, whether the designated weld location of each post of the plurality of posts is valid.

2. The method of claim 1, wherein determining, based on the image, whether the designated weld location of each post of the plurality of posts is valid includes:
determining, based on the image, whether there is contamination present on or around the weld location.

3. The method of claim 2, wherein the determining is performed using an artificial neural network trained to identify contamination.

4. The method of claim 3, wherein the artificial neural network is a convolutional neural network.

5. The method of claim 1, wherein determining, based on the image, whether the designated weld location of each post of the plurality of posts is valid includes:
determining, based on the image, whether each post is defective.

6. The method of claim 5, wherein the determining is performed using an artificial neural network trained to identify contamination.

7. The method of claim 6, wherein the artificial neural network is a convolutional neural network.

8. The method of claim 5, wherein defective includes bent, tilted or rotated.

9. The method of claim 5, wherein defective includes missing material.

10. The method of claim 1, wherein determining, based on the image, whether the designated weld location of each post of the plurality of posts is valid includes:
determining, based on the image, whether a lamella is already present at the weld location of each post.

11. The method of claim 10, wherein the determining is performed using an artificial neural network trained to identify contamination.

12. The method of claim 11, wherein the artificial neural network is a convolutional neural network.

13. The method of claim 1, further including:
determining, based on the image, whether the grid is valid.

14. The method of claim 13, wherein determining, based on the image, whether the grid is valid includes:
determining, based on the image, whether the grid is located in a designated location.

15. The method of claim 14, wherein the determining is performed using an artificial neural network trained to identify contamination.

16. The method of claim 15, wherein the artificial neural network is a convolutional neural network.

17. The method of claim 14, wherein determining, based on the image, whether the grid is located in a designated location includes determining whether the grid is tilted.

18. The method of claim 14, wherein determining, based on the image, whether the grid is located in a designated location includes determining whether the grid is rotated.

19. The method of claim 14, wherein determining, based on the image, whether the grid is located in a designated location includes determining whether the grid is flipped.

20. The method of claim 1, further includes:
storing a stage location associated with each valid weld location.
